(19) United States
(12) Patent Application Publication
(10) Pub. No.: US 2002/0113258 A1
(43) Pub. Date: Aug. 22, 2002

(54) Architecture for mask read-only memory

(76) Inventor: Yi-Min Cheng, Hsinchu (TW)

Correspondence Address: Howard J. Klein, Klein & Szekeres, LLP, 4199 Campus Dr., Ste. 700, Irvine, CA, 92612, US

(21) Appl. No.: 09/951,154

(22) Filed: Sep. 10, 2001

(30) Foreign Application Priority Data
Feb. 21, 2001 (TW) 090103981

(51) Int. Cl. H01L 27/108; H01L 29/94

(52) U.S. Cl. 257/296

(57) ABSTRACT

An architecture of a mask read-only memory (mask ROM) is provided. The architecture includes a base layer, a first doping layer formed on the base layer as a buried ground line of the Mask ROM, a second doping layer formed on the first doping layer with the first doping layer to form a switch, and a code layer formed on the first doping layer and the second doping layer and having data for being read via the switch in operation.

### FIELD OF THE INVENTION

The present invention relates to a mask read-only memory device, and more particularly to an architecture for a mask read-only memory.

### BACKGROUND OF THE INVENTION

A mask read-only memory (ROM) is a non-volatile memory. A mask read-only memory is widely used as a memory storage device for permanently storing date information such as game programs.

FIG. 1 is a schematic view showing the conventional architecture of a mask ROM formed by intersecting plural bit lines and word lines. A selected bit line intersects a point, a turned-on component, of a selected word line. The selected bit line is not connected to ground Vss through the turned-on component because the turned-on component is not connected to the selected bit line.

The conventional architecture is formed by a buried code type of manufacturing processes. Coding under gates means that sources and drains could be commonly used to reduce the sizes of mask ROMs. However, from coding to the product formation takes too much time to get time to market.

According to the method of data coding, mask ROMs can be classified into the contact type and via contact type. There is a trade-off relationship between the cycle time and the integration degree. However, the drains could not be commonly used with the sources in the foresaid methods of data coding. In order to overcome the foresaid drawbacks of the conventional architecture of mask ROMs, the present invention provides a improved architecture for raising market competitiveness of mask ROMs.

### SUMMARY OF THE INVENTION

It is therefore an object of the present invention to provide a improved architecture for raising market competitiveness of mask ROMs.

In accordance with an aspect the present invention, the architecture of a mask read-only memory (mask ROM) includes a base layer, a first doping layer, a second doping layer and a code layer.

The first doping layer is formed on the base layer as a buried ground line of the mask read-only memory.

The second doping layer is formed on the first doping layer with the first doping layer to form a switch.

The code layer is formed on the first doping layer and the second doping layer and having data for being read via the switch in operation.

Preferably, the first doping layer and the second doping layer have different qualities.

Preferably, the first doping layer is a P-typed doping layer and the second doping layer is an N-typed doping layer.

Preferably, the buried ground line is a word line.

Preferably, the switch is a diode.

Preferably, the code layer is a via contact type of coding.

Preferably, the code layer is a contact type of coding.

In accordance with another aspect of the present invention, the architecture of a mask read-only memory (mask ROM) includes a plurality of bit units and a metal layer.

The plurality of bit units respectively have a buried ground line.

The metal layer is disposed above the plurality of bit units for connecting with the buried ground line.

Preferably, the buried ground line is a word line.

Preferably, the mask read-only mask is formed by a via contact type of coding.

Preferably, the mask read-only mask is formed by a contact type of coding.

In according to another aspect of the present invention, the mask read-only mask (mask ROM) includes a first memory region, a second memory region and an active isolation device.

The active isolation device is used for making the first memory region and the second memory region isolated.

In addition, the active isolation device includes plural active components, and the active components have gates connecting with a ground potential.

Preferably, the active components are read-only mask transistors.

Preferably, the active components have gates connecting respectively with a word line.

The present invention may best be understood through the following descriptions with reference to the accompanying drawings, in which:

### BRIEF DESCRIPTION OF THE DRAWINGS

FIG. 1 is a schematic view showing the conventional architecture of a mask read-only memory formed by intersecting plural bit lines and word lines;

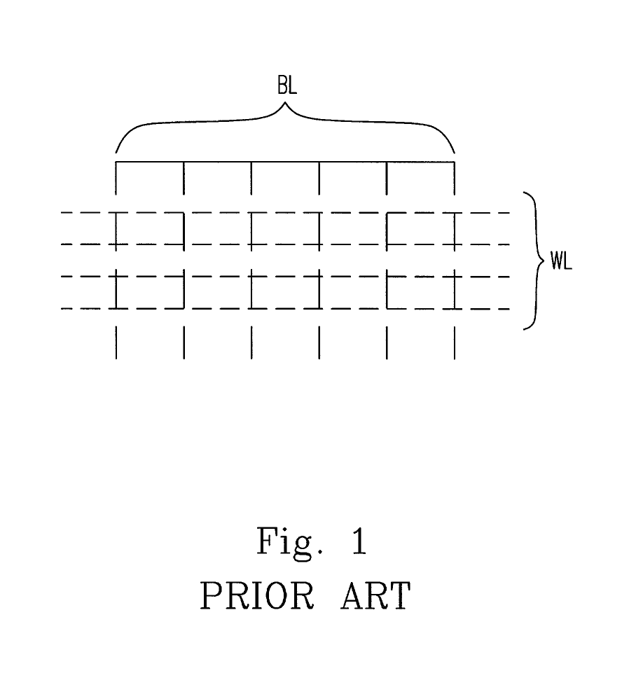

FIG. 2 is a schematic view showing the first architecture of the mask read-only memory according to the preferred embodiment of the present invention;

FIG. 3 is a schematic view showing the layout and sectional view of the preferred embodiment of the present invention;

FIG. 4 is a schematic view showing the second architecture of the mask read-only memory according to the preferred embodiment of the present invention; and

FIG. 5 is a schematic view showing the third architecture of the mask read-only memory according to the preferred embodiment of the present invention.

### DETAILED DESCRIPTION OF THE PREFERRED EMBODIMENTS

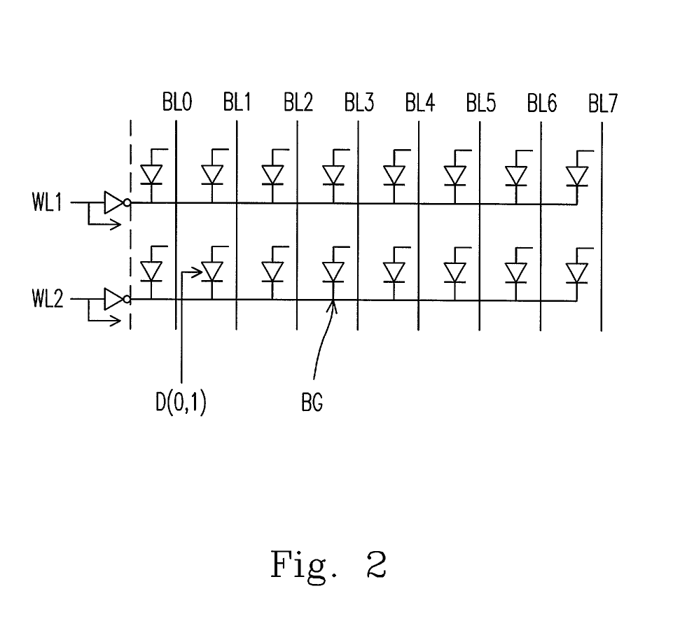

Please refer to FIG. 2. Each cell is composed of a diode. An N terminus of a diode is connected to the N terminus of the adjacent diode of the identical word line (WL) to form a buried ground (BG) line. Whether the buried ground line is connected to Vss is determined a specific component of the word line. The specific component of the word line could be an inverter. Whether the cell is connected to the bit line (BL) is determined by the via contact type of coding. The performance is described as follows.

If BL1 is selected by the decoder, the BL1 is charged to a high logic potential. If BL0 is selected by the decoder, the diode D (0,1) is activated and connected to BL1 through via code, and BL1 is discharged to low potential.

Therefore, the foresaid diode is used as a switch to control the data reading. The diode is turned on or turned off to represent a logic “1” or a logic “0” in binary.

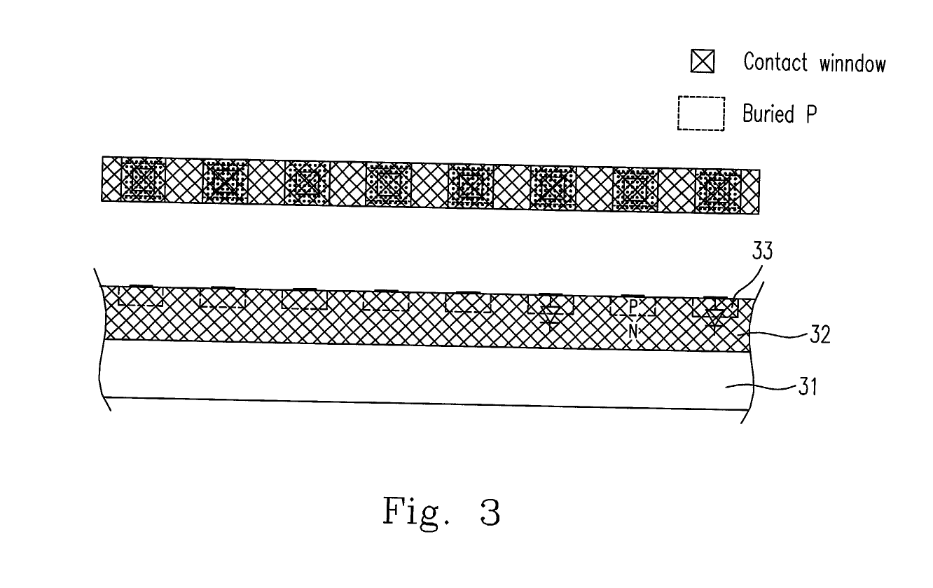

Please refer to FIG. 3. The upper portion in FIG. 3 is a layout showing the architecture, and the lower portion in FIG. 3 is a sectional view showing the architecture of a mask read-only memory according to the present invention.

The architecture of a mask read-only memory provided by the present invention includes a base layer 31, an N-typed doping layer 32 and a P-typed doping layer 33. The manufacturing process of the architecture is described as follows.

The N-typed doping layer 32 is formed. The P-typed dopant is implanted into a reserved position of a contact layer (not shown) included in the N-typed doping layer 32 to form the P-typed doping layer 33. The concentration and depth of the implanted P-typed dopant are controlled and not diffused to edges of the N-typed doping layer 32, and the contact layer is wrapped by the horizontal of the P-typed doping layer 33. The vertical of the P-typed doping layer 33 is used for forming a buried ground line. The contact layer is formed, and metal 1 is coated on the contact layer. Whether the diode is connected to the bit line (metal 2) is selected by the via type of coding.

The important characteristics of the present invention are that the diode is under the buried ground line, and the diode is vertically and parallel connected to the buried ground line. Furthermore, the diode and the buried ground line are fabricated according to the concentration and depth of the buried P as shown in the FIG. 3.

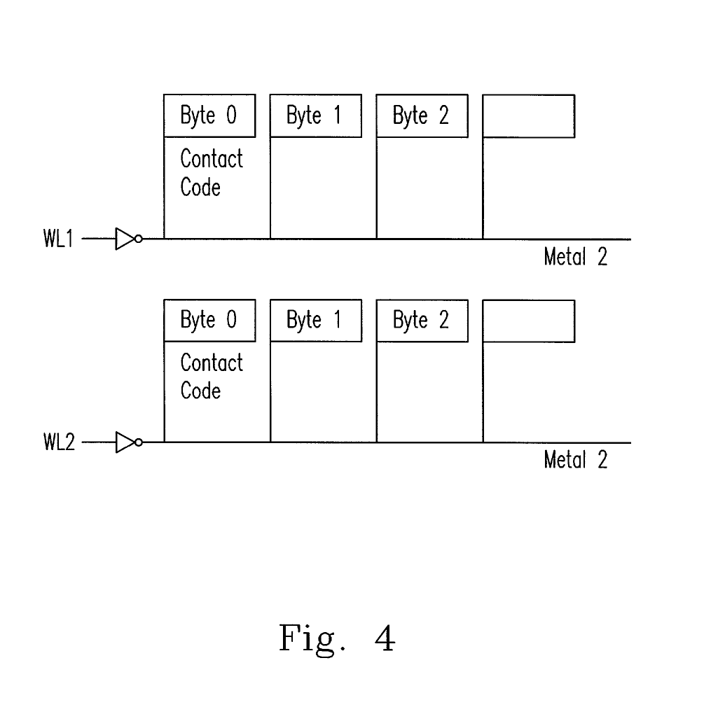

Please refer to FIG. 4. Each word unit includes 8 words for using contact type of coding and parallel connecting to the metal 2 by using common buried ground line and N-typed doping layer. So that the layout is more regular.

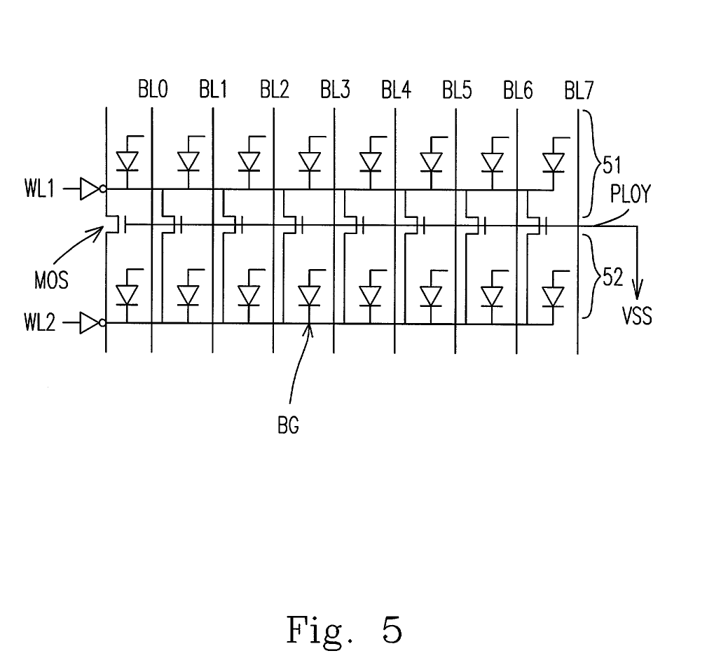

Please refer to FIG. 2 and FIG. 5. FIG. 5 is obtained based on FIG. 2. In FIG. 5, an active isolation device is added between two memory region for isolating the first memory region 51 and the second memory region 52. The active isolation device includes a plurality of active components, and the gates of the active components are electrically connected to a ground potential. The active components could be MOS components. The gates of the active components are respectively connected to a word line.

In addition, if the product is manufactured by the double metal process and the contact type of coding, the word lines use metal 1 and the layout is changed to form horizontal and parallel connected word lines. Just global Vss is needed so that the word lines could not be arranged from byte 0 to byte N.

According to the architecture of the mask read-only memory provided by the present invention, the delay time of the word line is much decreased, and the impedance of the metal 2 connected to the global Vss is very low to increase the horizontal speed. Furthermore, the size of the architecture is much smaller.

Hence, the drawbacks of the conventional mask read-only memory is improved by the present invention.

While the invention has been described in terms of what are presently considered to be the most practical and preferred embodiments, it is to be understood that the invention need not be limited to the disclosed embodiment. On the contrary, it is intended to cover various modifications and similar arrangements included within the spirit and scope of the appended claims which are to be accorded with the broadest interpretation so as to encompass all such modifications and similar structures. Therefore, the above description and illustration should not be taken as limiting the scope of the present invention which is defined by the appended claims.

What is claimed is:

1. An architecture of a mask read-only memory (mask ROM), comprising:
a base layer;
a first doping layer formed on said base layer as a buried ground line of said Mask ROM;
a second doping layer formed on said first doping layer with said first doping layer to form a switch; and
a code layer formed on said first doping layer and said second doping layer and having data for being read via said switch in operation.

2. The architecture according to claim 1, wherein said first doping layer and said second doping layer have different qualities.

3. The architecture according to claim 2, wherein said first doping layer is a P-typed doping layer and said second doping layer is an N-typed doping layer.

4. The architecture according to claim 1, wherein said buried ground line is a word line.

5. The architecture according to claim 1, wherein said switch is a diode.

6. The architecture according to claim 1, wherein said code layer uses via code.

7. The architecture according to claim 1, wherein said code layer uses contact code.

8. An architecture of a mask read-only memory (mask ROM), comprising:
a plurality of bit units respectively having a buried ground line; and
a metal layer disposed above said plurality of bit units for connecting with said buried ground line.

9. The architecture according to claim 8, wherein said buried ground line is a word line.

10. The architecture according to claim 8, wherein said mask read-only mask uses via code.

11. The architecture according to claim 8, wherein said mask read-only mask uses contact code.

12. An architecture of a mask read-only mask (mask ROM), comprising:
a first memory region;
a second memory region; and
an active isolation device for making said first memory region and said second memory region isolated.

13. The architecture according to claim 12, wherein said active isolation device comprises plural active components, and said active components have gates connecting with a ground potential.

14. The architecture according to claim 13, wherein said active components are read-only mask transistors.

15. The architecture according to claim 13, wherein said active components have gates connecting respectively with a word line.
